(19) United States
(12) Patent Application Publication
(10) Pub. No.: US 2005/0037615 A1
(43) Pub. Date: Feb. 17, 2005

(54) In-line spectroscopy for process monitoring

(76) Inventors: Dario Cabib, Timrat (IL); Robert A. Buckwald, Ramat Yishay (IL)

Correspondence Address: Mark M. Friedman;Bill Polkinghorn, Discovery Dispatch, 9003 Florin Way, Upper Marlboro, MD, 20772, US

(21) Appl. No.: 10/494,301

(22) PCT Filed: Nov. 6, 2002
(86) PCT No.: PCT/IL02/00882

(30) Foreign Application Priority Data
Nov. 6, 2001 (US) 60331002
Mar. 4, 2002 (US) 60361314

(51) Int. Cl. B05D 1/00; H01L 21/302; H01L 21/461

(52) U.S. Cl. 438/689

(57) ABSTRACT

A method for processing a workpiece and an associated processing chamber and analytic instrument. A layer of a material such as a low-K dielectric is applied to a workpiece such as a semiconductor wafer. During the application, and/or before or during subsequent processing, a property of the layer is measured by steps including exciting a portion of the layer with incident light and monitoring light such as Raman scattered light that is emitted from that portion of the layer in response to the incident light, via a probehead that may be inside or outside the chamber housing. The analytic instrument includes the probehead and two sources of excitation light at two different wavelengths.

### FIELD AND BACKGROUND OF THE INVENTION

The present invention relates to in-line monitoring of a workpiece undergoing processing and, more particularly, to in-line monitoring of a workpiece, such as a semiconductor wafer to which a layer of low-K dielectric is applied, using Raman spectroscopy.

The semiconductor industry is gradually introducing new dielectric materials as electrical insulators of-integrated circuits, instead of SiO₂. These materials, so called low-K dielectrics, have lower dielectric constants than SiO₂. This change is driven by the constant reduction of the size of the smallest features on a chip, and by the adoption of copper as the metal used for the electrical connections, instead of aluminum. These new dielectric materials must comply with a long list of very stringent requirements, with respect to their physical and chemical properties. These requirements include high mechanical stability, good adhesion to the substrate, the ability to withstand thermal stresses during the many subsequent steps, such as lithography, planarization and deposition of other materials, until the final packaging of the product, and high chemical purity and stability. Many of these materials are manufactured with added porosity in their bulk, to reduce their overall density, and are hygroscopic. As a result, moisture uptake from the environment, which is detrimental to the intended function of these dielectrics, must be controlled. Monitoring the thin film properties of the low-K materials after annealing or curing is therefore vital to the proper functioning of the final integrated circuit device and its long-term reliability.

Furthermore, the semiconductor industry is requiring better and better repeatability of the thin film parameters from wafer to wafer, and handles ever larger and more expensive wafers. As a consequence the need for in-situ/in-line non-contact, non-invasive monitoring of every product wafer, during and/or at the end of certain production processes, is increasing. This trend is replacing, in many instances, traditional off-line tests, and the so-called test wafers. Test wafers are representative wafers, which are taken out of the production line or introduced to the production line at different production stages, with the specific purpose of being tested to monitor the production process. In view of the high wafer costs, these from the production line for off-line testing cannot be used for the final product, and must be discarded. Second, by the time the results of the test are known and analyzed, many other wafers have gone through the production processes. These wafers may have the same unsuitable characteristics as the tested wafer, and so must be scrapped. Reduction of the need for test wafers therefore would be a significant cost saving for the semiconductor industry.

Raman spectroscopy is known to be useful in measuring properties; of other materials, that are of interest in the case of low-K dielectric layers. In this regard, Raman spectroscopy has certain advantages over other optical analytic tools, such as FTIR (Fourier Transform Infrared) spectroscopy and NIR (Near Infrared) spectroscopy. Richard L. McCreery described some of these advantages on page 12 of Raman Spectroscopy for Chemical Analysis (Wiley Interscience, 2000) as follows:

The attraction of Raman spectroscopy for chemical analysis is derived from the combination of many of the advantages of FTIR with those of NIR absorption, plus a few benefits unique to Raman . . . Like NIR, Raglan spectra can be acquired noninvasively, and sampling can be simple and fast. Like FTIR, Raman scattering probes fundamental vibrations with high spectral resolution. Although the selection rules differ for FTIR and Raman, the information is similar and both are amenable to spectral libraries and fingerprinting . . . Raman combines the high spectral information content of FTIR with the sampling ease and convenience of NIR absorption. In addition, Raman has some added features based on resonance and/or surface enhancement, polarization measurements, and compatibility with aqueous samples.

An additional advantage of Raman spectroscopy over both FTIR and NIR, which may be important specifically in the semiconductor field, is the capability, in the case of Raman signals, of focusing the optical collection system to smaller spot sizes on the sample, due to the fact that the dispersive Raman technique uses shorter wavelengths than the other two methods. Obviously, the need to analyze the smallest possible regions on the sample derives from the fact that product wafers are patterned in complicated ways with three dimensional microscopic structures, thereby leaving very small, if any, uniform regions on the wafer surface. This advantage may even be amplified in the future, as time goes on, because the trend in the semiconductor industry is to further reduce the chip sizes, while increasing their computing power and the amount of memory cells contained in them. The industry foresees that the smallest feature sizes (transistor critical dimension, known in the industry as “CD”) will reach the order of 0.1 microns or less, in the near future. This will bring the low-K materials feature sizes down to 0.5 to 1 micron or less, at the higher levels of the interconnecting layers. This is near the limit of resolution of visible light, and smaller than the limits of resolution of FTIR and NIR.

It is known that certain material properties, that also are of interest in connection with low-K dielectrics, can be measured by Raman spectroscopy. Note that the relevant Raman spectra heretofore have been measured using research-grade Raman spectrographs, which are not suitable for use in the environment of an industrial production line, and in particular are not suitable for in-line monitoring of semiconductor wafers in a fab.

One such property is moisture content. As noted above, many low-K materials, and in particular porous low-K materials, tend to be hygroscopic. The Raman spectrum of water at several temperatures was reported by David N. Whiteman et al. in “Measurement of an isosbestic point in the Raman spectrum of liquid water by use of a backscattering geometry”, Applied Optics vol. 38 no. 12 pp. 2614-2615, which is incorporated by reference for all purposes as if fully set forth herein.

### SUMMARY OF THE INVENTION

Recently, compact Raman probeheads, for illuminating a sample with laser radiation and for collecting the Raman spectrum from the sample after filtering out the directly scattered laser radiation, have become available. One such Raman probehead is the Mark II Filtered Probehead, available from Kaiser Optical Systems, Inc. of An Arbor Mich. USA. Another such Raman probehead is the probehead of the RP-1 spectrograph, available from SpectraCode of West Lafayette Ind. USA. These probeheads have been used for applications other than in-line monitoring of industrial processes. For example, the RP-1 spectrograph is advertised as suitable for “point and shoot” identification of polymer resins. The present invention is based on the realization that these probeheads can indeed be used for in-line monitoring of industrial processes such as the application of a low-K dielectric layer to a silicon wafer and the subsequent annealing or curing of the layer.

Therefore, according to the present invention there is provided a method of processing a workpiece, including the steps of: (a) applying a layer of a first material to the workpiece; and (b) measuring a property of the layer by steps including: (i) exciting at least a first portion of the layer with incident light, and (ii) monitoring light that is emitted from the at least first portion in response to the incident light.

Although the scope of the present invention includes the application of any material to any workpiece, the present invention is directed primarily towards the application of a layer of low-K dielectric to a workpiece such as a silicon wafer.

Preferably, the property that is measured is selected from the group consisting of dielectric constant, index of refraction, moisture content, purity, thermal stability, cure progress, glass transition temperature, stress, Young's modulus, hardness, thermal expansion coefficient, adhesion strength, chemical resistance, chemical compatibility with a second material, permeability, gap fill capability, planarization ability, layer thickness, void content and durability under chemical mechanical polishing.

The measuring may be effected either during the application of the layer or subsequently, for example while the layer is subjected to a subsequent treatment such as heating; or while a photoresist is stripped from the workpiece.

Preferably, the monitoring includes measuring a spectrum of the light that is emitted in response to the incident light. Alternatively, the monitoring includes measuring the light that is emitted in response to the incident light at only a single wavenumber, or at a plurality of discrete wavenumbers. Most preferably, the monitoring is effected substantially simultaneously with respect to a plurality of locations on the workpiece from which light is emitted in response to the incident light.

Preferably, the incident light is substantially monochromatic. Alternatively, the exciting is effected using a plurality of different discrete incident wavelengths, either simultaneously or sequentially.

Preferably, the light that is emitted in response to the incident light includes Raman scattered light. More preferably, the measuring further includes subjecting at least a second portion of the workpiece to a second measurement technique such as spectroscopy, ellipsometry, reflectometry or transmissometry. The spectroscopy may be fluorescence spectroscopy. The spectroscopy may be in the visible region of the spectrum, in the near infrared region of the spectrum, or in the mid-infrared region of the spectrum. Preferably, the first and second portions of the workpiece are substantially identical.

Alternatively, the light that is emitted in response to the incident light includes fluorescence.

Preferably, the exciting and the monitoring are effected using a probehead.

Preferably, the processing is effected inside a chamber, and the probehead is inside the chamber too. Alternatively, the probehead is outside the chamber, with the exciting and the monitoring being effected via an optical window.

Furthermore, according to the present invention there is provided a chamber for processing a workpiece, including: (a)a chamber housing wherein the workpiece is placed for processing and (b) a probehead for exciting at least a portion of the workpiece with incident light and for receiving light that is emitted from the at least portion in response to the incident light.

Preferably, the light that is emitted from the at least portion of the workpiece in response to the incident light includes Raman scattered light. Alternatively, the light that is emitted from the at least portion of the workpiece in response to the incident light includes fluorescence.

Preferably, the chamber also includes one or more lasers, or alternatively a xenon lamp, for providing the incident light, and also a spectrograph for analyzing the light that is emitted in response to the incident light.

Preferably, the probehead is inside the chamber housing. Alternatively, the probehead is outside the chamber housing, and the chamber further includes a window, in the chamber housing, through which the probehead delivers the incident light to the at least portion of the workpiece that is to be excited and through which the probehead receives the light that is emitted from the excited at least portion of the workpiece.

Preferably, the chamber also includes an ellipsometer for effecting ellipsometry of the at least portion of the workpiece.

The scope of the present invention also extends to a cluster tool that includes a chamber of the present invention.

Furthermore, according to the present invention there is provided an analytic instrument including: (a) a Raman probehead for exciting an object with incident light and for receiving Raman-scattered light from the object; (b) a first source for providing the incident light at a first wavelength; and (c) a second source for providing the incident light at a second wavelength.

Preferably the sources include respective lasers.

Preferably, the sources provide the incident light to the Raman probehead at least in part along a common optical path, and the analytic instrument further includes a mechanism that directs the incident light from both sources to the common optical path. Most preferably, the mechanism is stationary, i.e., has no moving parts. Preferably, the mechanism includes a dichroic filter that reflects the incident light of one of the sources and transmits the incident light of the other source.

Furthermore, according to the present invention there is provided a method of processing a workpiece bearing a layer of a first material, including the steps of: (a) exciting at least a first portion of the layer with incident light, and (b) monitoring light that is emitted from the at least first portion in response to the incident light, in order to measure a property of the layer.

### BRIEF DESCRIPTION OF THE DRAWINGS

The invention is herein described, by way of example only, with reference to the accompanying drawings, wherein:

FIGS. 1A and 1B are two portions (around 1610 cm⁻¹ and 2220 cm⁻¹, respectively,) of a Raman difference spectrum of a SiLK™ layer on silicon;

FIG. 2 shows ratios of peak heights for six SiLK™-on-silicon samples;

FIG. 3 shows Raman spectra of a SiCOH material before and after annealing;

FIG. 4 shows the Raman spectrum of a 1000 Å layer of “Black Diamond” on silicon;

FIG. 5 shows the Raman spectrum of a 3300 Å layer of “ELK-II” on silicon;

FIG. 6 shows a plot of the ratios of the 3000 cm⁻¹ peak to the 950 cm⁻¹ peak for the spectra of FIGS. 4 and 5 and for the two spectra of FIG. 3;

FIG. 7 shows Raman spectra of reference FSG samples;

FIG. 8 is a combined plot of calibration atomic % F for the samples of FIG. 7 and inferred atomic % F for three other FSG samples;

FIG. 9 shows inferred CH₃ carbon densities for eight samples of low-K dielectrics;

FIG. 10 shows a plot of the ratios of the 3000 cm₋₁ peak to the 950 cm⁻¹ peak for the samples of FIG. 9 plus one other sample:

FIGS. 11, 12 and 14 are schematic illustrations, in cross-section of processing chambers of the present invention.

FIG. 13 shows, schematically, how the measurement systems of FIGS. 11, 12 and 14 alternate between two excitation wavelengths;

FIG. 15 is a schematic illustration of a cluster tool of the present invention;

FIG. 16 shows fluorescence spectra of six SiCOH samples;

FIG. 17 shows the first derivatives of the curves of FIG. 16;

FIG. 18 is an image of a spectrally imaged region of one of the SiCOH samples of FIGS. 16 and 17.

### DESCRIPTION OF THE PREFERRED EMBODIMENTS

The present invention is of a method of processing a workpiece, while monitoring the processing using an optical excitation technique such as Raman scattering. The monitoring of the present invention may be simultaneous with or subsequent to the processing, in the same chamber or in a different chamber. Specifically, the present invention can be used to deposit and anneal or cure a layer of low-K dielectric on a semiconductor wafer.

The principles and operation of workpiece processing according to the present invention may be better understood with reference to the drawings and the accompanying description.

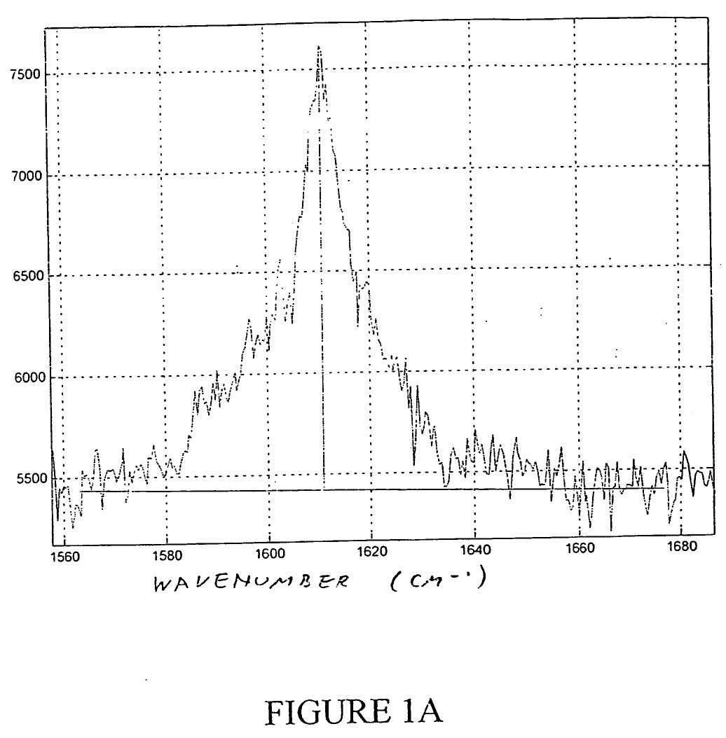

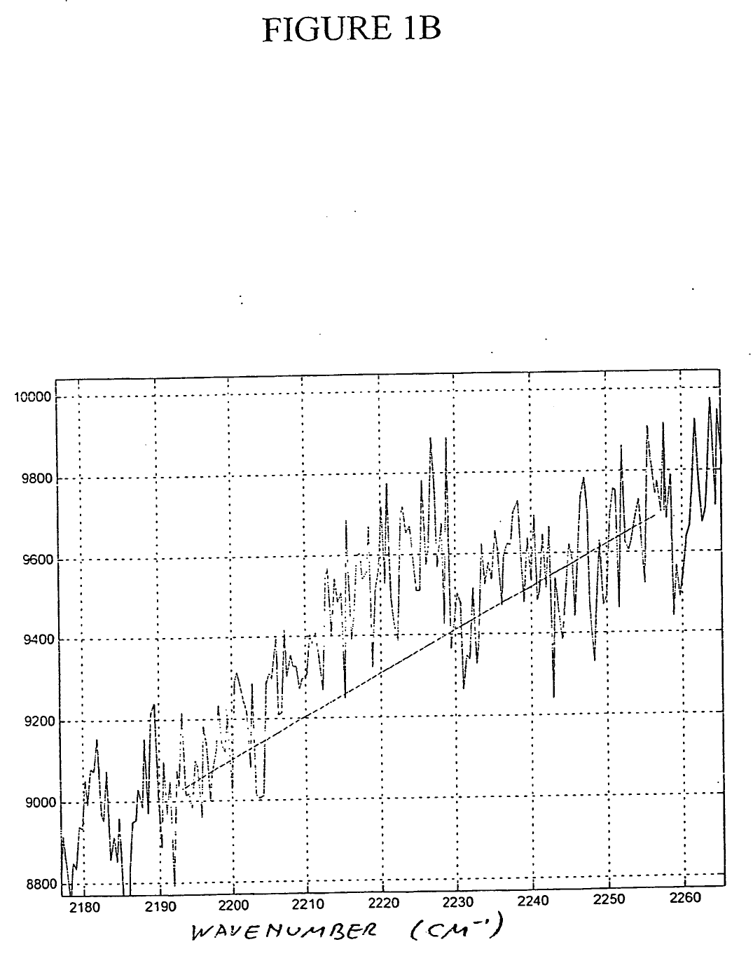

We have performed our own Raman spectral measurements of properties of interest in low-K dielectrics on silicon wafers. Referring now to the drawings, FIGS. 1A through 10 illustrate some of these measurements.

### 1. Curing of SiLK™

SiLK™ is a low-K dielectric material that is manufactured and sold by Dow Chemical Company of Midland Mich. USA. FIGS. 1A and 1B are portions of a Raman difference spectrum of a SiLK™ layer about one micron thick on silicon, around 1610 cm⁻¹ and 2220 cm⁻¹, respectively, showing the difference spectral peaks at those wavenumbers. The straight lines were drawn by taking the average spectra on either sides of the peaks, taking into account the overall slope vs. wavenumber, and joining the averages. In each Figure, the difference between the average spectrum in the region of the local maximum and the value of the straight line directly below the local maximum is taken as the peak height.

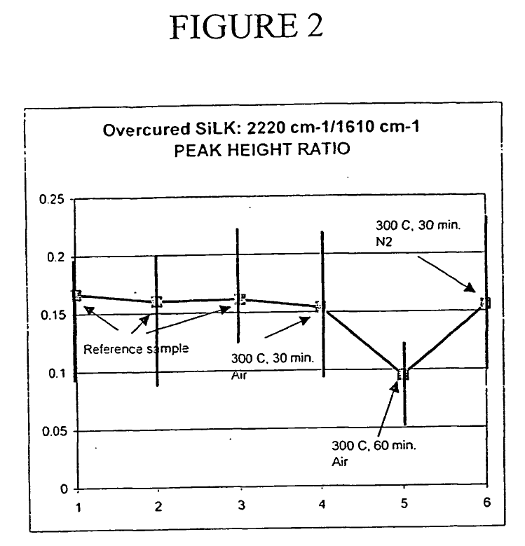

The ratio of the intensity of the two peaks changes with curing temperature and time. FIG. 2 shows ratios of peak heights for three SiLK™-on-silicon “reference samples” cured by Dow Chemical Company (left) vs. three SiLK™-on-silicon cured by Dow Chemical Company and then further cured by us by heating to 300° C. for the indicated times in the indicated atmospheres. The vertical bars are error bars due to the noise on the Raman signal. The air atmosphere, being more reactive than the nitrogen atmosphere, is expected to result in a larger change of the spectral features.

### 2. Annealing of SiCOH

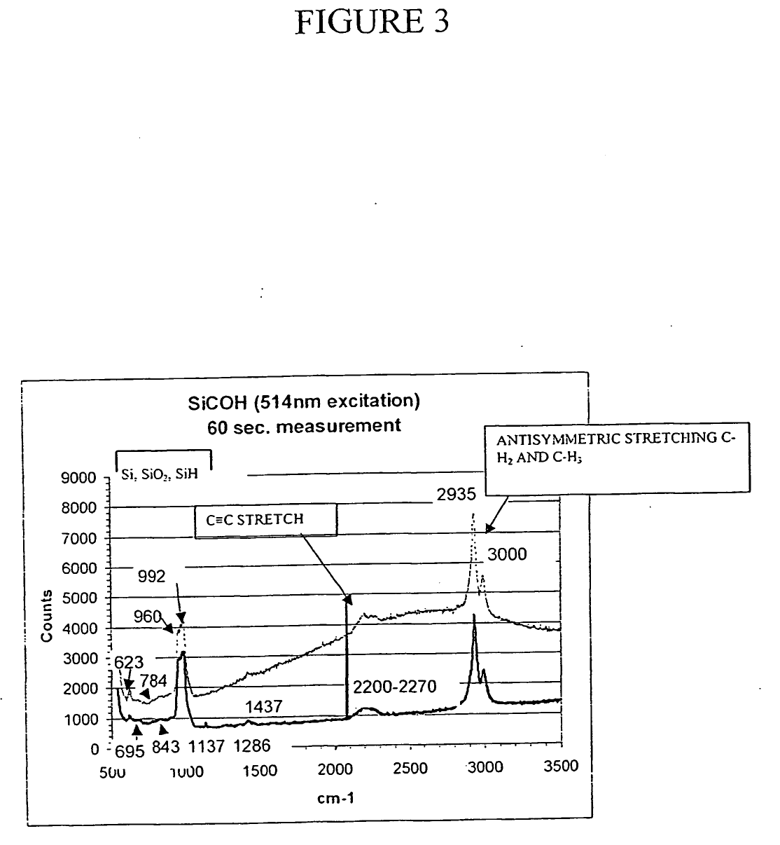

An 11,000 Å thick layer of a low-K “SiCOH” material on silicon was prepared as described by A. Grill et al. in “SiCOH dielectrics: from low-k to ultralow-k by PECVD”, Proceedings of the Advanced Metallization Conference 2001, Materials Research Society, Warrendale Pa.: p. 253. FIG. 3 shows Raman spectra before (lower curve) and after (upper curve) annealing. The spectral features in the 500 cm⁻¹ to 1000 cm⁻¹ range are characteristic of silicon, silicon oxide and silicon-hydrogen bonds. Spectral features above that range are caused by CH₂ and CH₃ bonds. The spike around 2100 cm⁻¹ is a spurious spike caused by cosmic rays. The ratio of the peak at 2935 cm⁻¹ to the peak at 3000 cm⁻¹ changes from 2.35 before annealing to 2.75 after annealing.

### 3. Low-K dielectric layer thicknesses

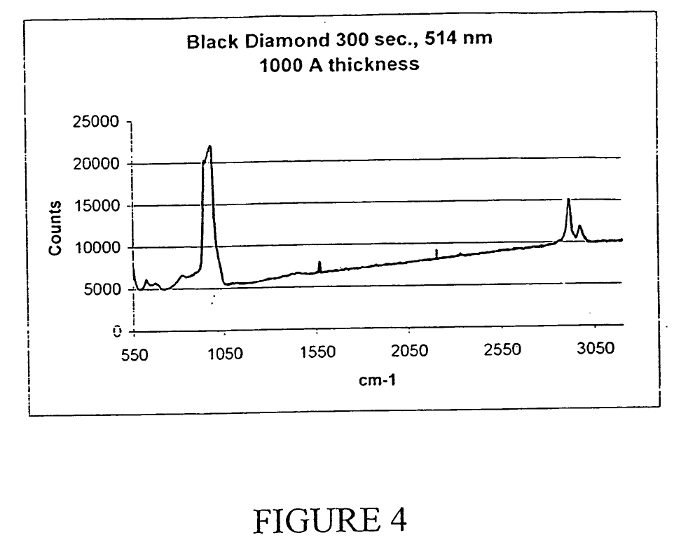

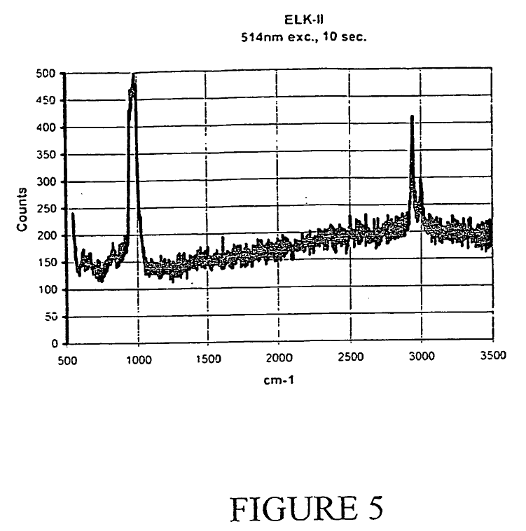

FIG. 4 shows the Raman spectrum of a 1000 Å layer of Black Diamond™ of Applied Materials Inc. of Santa Clara Calif. USA on silicon. FIG. 5 shows the Raman spectrum of a 3300 Å layer of a porous SiO₂ film with carbon and hydrogen, (trade name “ELK-II”, also of Applied Materials Inc.) on silicon.

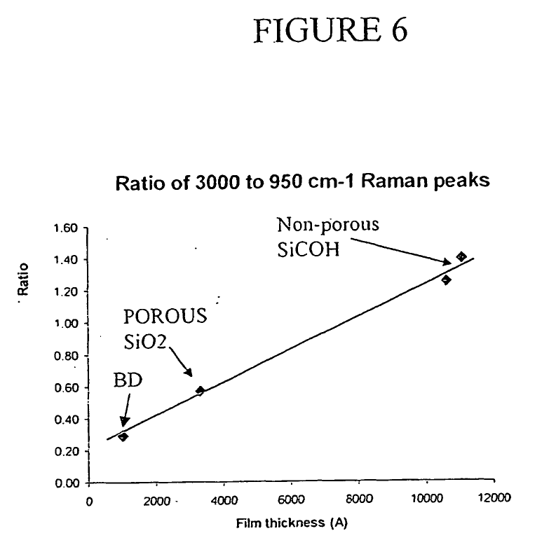

FIG. 6 shows a plot of the ratio of the 3000 cm⁻¹ peak to the 950 cm⁻¹ peak, as a function of film thickness for the spectra of FIGS. 4 and 5 and for the two spectra of FIG. 3. This plot shows a linear correlation between this ratio and the layer thickness, imputed to the fact that the 950 cm⁻¹ peak is a pure silicon peak, whereas the double peak at 3000 cm⁻¹ is solely due to the presence of carbon in the film. As a result, the thicker the film, the larger the relative intensity of the 3000 cm⁻¹ peak with respect to the 950 cm⁻¹ peak.

### 4. Composition of Fluorinated Silica Glass (FSG) on silicon

FSG has been known and used for many years in the semiconductor industry as a dielectric material with a lower dielectric constant than SiO₂. Its lowest achieved dielectric constant of 3.5 is not quite as low as the semiconductor industry will need in the future, but it is based on a safe and known process. As a result, there is a trend in the semiconductor industry today to continue to use FSG with as low a dielectric constant as possible for as long as possible, while more advanced materials with dielectric constants lower than 3 are being developed.

It turns out that the critical parameter for the determination of K in FSG is the atomic % of fluorine (or % F: see C. Steinbrüchel and B. L. Chin, Copper Interconnect Technology, SPIE Press Vol. TT46 (2001) Chapter 5, “Interlayer dielectrics”, p. 53). A common method of measuring atomic % F, among others, is FTIR absorption, through the ratio of Si—F to Si—O absorption peaks (950 to 1060 cm⁻¹ lines). Unfortunately, the FTIR method is a cumbersome laboratory method, not suitable for in-situ or in-line measurements of wafers in the semiconductor industry.

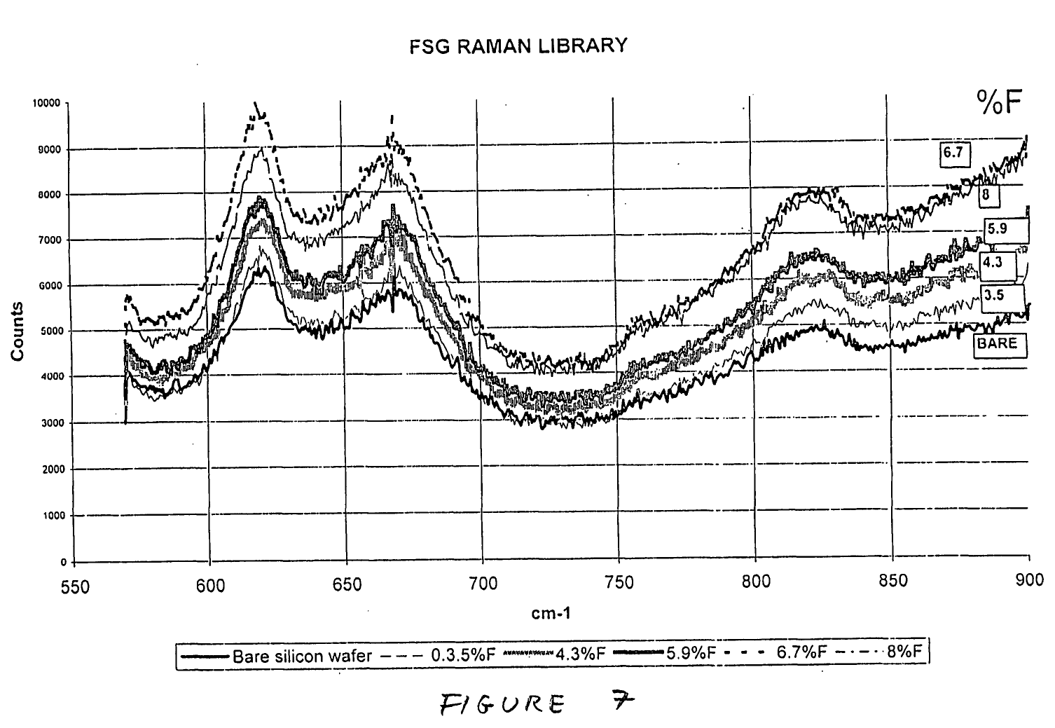

To establish whether there exists a correlation between the FTIR and Raman spectra of FSG samples of different atomic % F, 5000-Å-thick FSG films of different atomic % F on silicon were characterized by a standard FTIR absorption technique. Then the Raman spectra of the films were measured and used as input to a computer 200 program called “Unscrambler”, available from CAMO Inc. of Woodbridge N.J. USA. Unscrambler was used in the PLS (Partial Least Squares) mode to build a library of correspondence between the Raman spectra and the atomic % F as measured by FTIR. FIG. 7 shows the Raman spectra that were used to build the library.

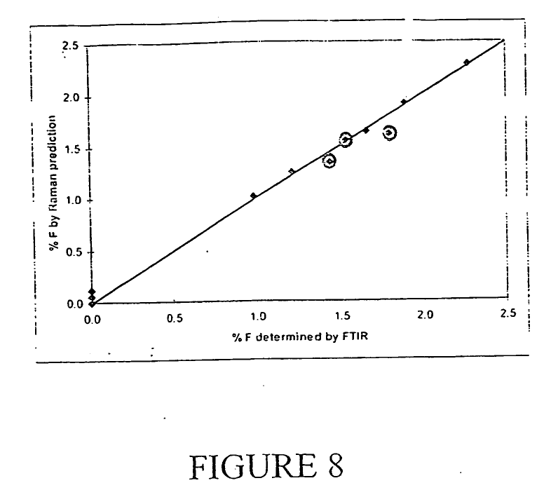

This library was used to predict, from Raman spectra, the atomic % F of three other samples whose atomic % F was measured independently by FTIR. FIG. 8 shows the results. The circled diamonds are the three test samples. The uncircled diamonds are the library samples.

### 5. Density of C in CH₃ bonds of Porous Low-K Materials

Several low-K samples on silicon were measured by microscopic Raman spectroscopy. The samples were of the type carbon-doped-silicon-oxide, and were deposited by different PECVD methods. The samples had varying degrees of porosity, with the porosity having been obtained via reactions involving the formation of CH₃ bonds in the low-K layers.

The following notation is used in the following development:
d₁=film thickness of the low-K dielectric layer
d₂=absorption depth of the incident laser wavelength in the silicon substrate
ρ₁=number density of the C—H bonds in the low-K dielectric layer (cm⁻⁻³)
ρ₂=number density of the Si—Si bonds in the silicon substrate (cm⁻⁻³)
I=intensity of the Raman low shift peak among the double peak at 3000 cm⁻¹
I₀=intensity of the Raman peak around 950 cm⁻¹, sensitive only to Si bonds
α=proportionality constant due to different instrument response and different
   Raman cross sections of the C—H₃ bonds in the two separate wavenumber ranges

Assuming that the measurement spot size is the same for all samples, the following holds to a first approximation:

$$\frac{I}{{I}_{0}} = α \frac{{ρ}_{1} {d}_{1}}{{ρ}_{2} {d}_{2}} = β {ρ}_{1} {d}_{1} \qquad ( 1 )$$

where

$$β = \frac{α}{{ρ}_{2} {d}_{2}} .$$

Using the ratio I/I₀ eliminates the effects of drifts or changes in laser intensity from sample to sample, as well as other measurement conditions that may change from sample to sample.

If d₁ is known for each measurement, then ρ₁ can be found, provided the constant β can be found or calibrated independently. From equation (1),

$${ρ}_{1} = \frac{I}{{I}_{0}} {( β {d}_{1} )}^{- 1} = γ \frac{I}{{d}_{1} {I}_{0}} \qquad ( 2 )$$

where γ=β⁻¹ (cm²).

The mass density of carbon atoms linked to H₃ isρ₁ W_{C} where W_{C}, the atomic weight of carbon, is 20×10⁻²⁴ g. The density of ELK-II is 1.28 g/cm³ (Ilanit Fisher et al. “Study of porous silica-based films as low-k dielectric material”, paper accepted for publication in The MRS Proceedings, June 2002). This measured density was used to estimate γ from equation (2), and then to estimate ρ₁ for other porous low-K films. Once γ is known, a Raman measurement combined with a film thickness measurement yields ρ₁ of an unknown film, also from equation (2).

The atomic % of the ELK-II components are: Si: 24%, O: 44%, C: 15% and H: 17% (Ilanit Fisher, op. cit.). With one carbon atom for three H atoms in CH₃, and assuming that all the H atoms are in CH₃ groups, the atomic % of carbon atoms linked to H₃ is 17/3%=5.67%. The weight density of the CH₃ carbon atoms then is

$$\frac{5.67 • {W}_{C} • 1.28 \text{g/} {cm}^{3}}{17 {W}_{H} + 15 {W}_{C} + 44 {W}_{O} + 24 {W}_{Si}} = 5.5 \times {10}^{2} \text{g/} {cm}^{3} .$$

The number density of CH₃ carbon atoms then is ρ₁=2.76×10²¹ cm⁻⁻³. Plugging this value into equation (2) gives γ.

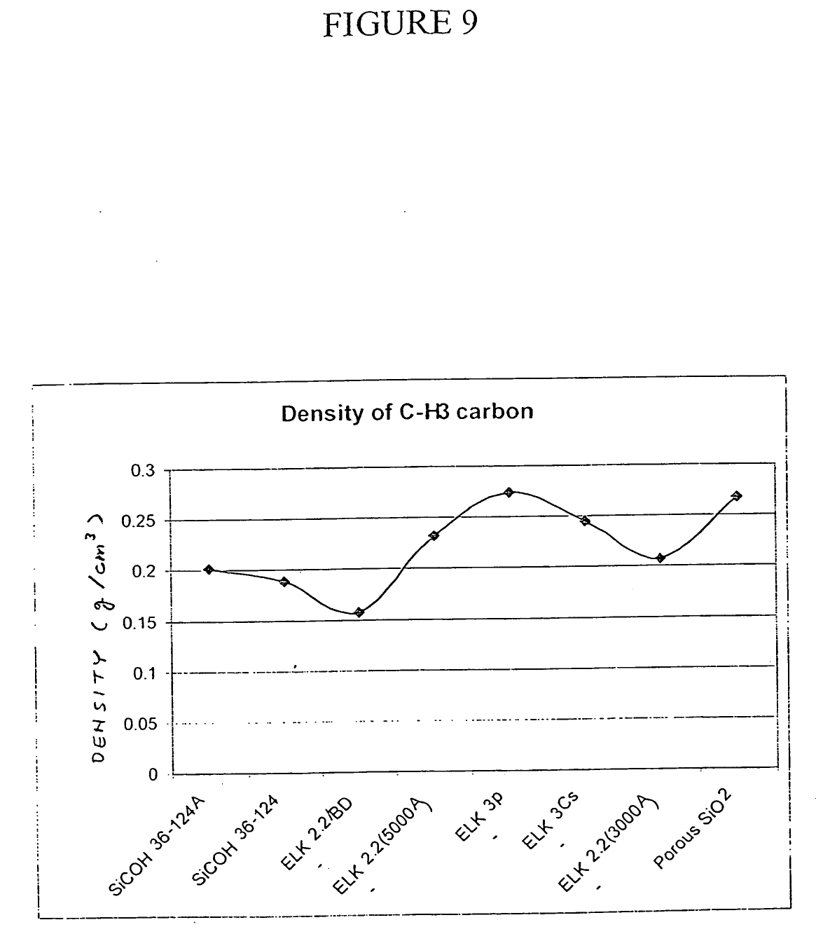

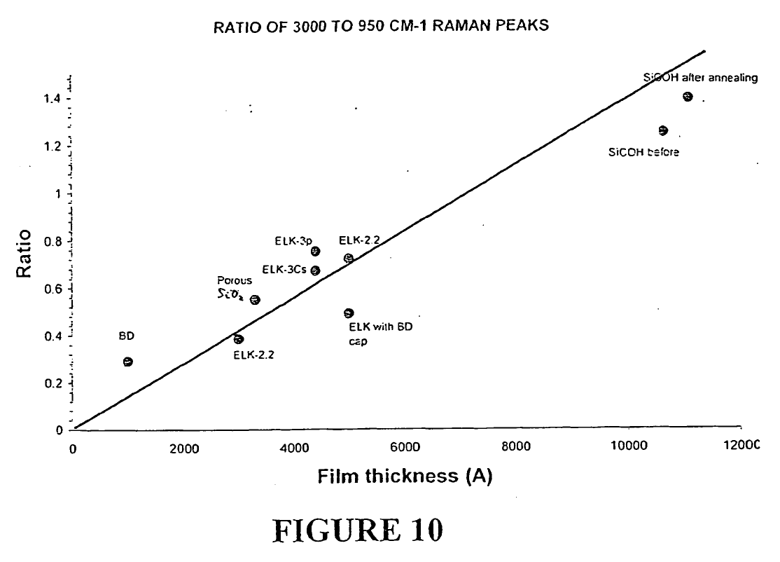

FIG. 9 shows calculated CH₃ carbon mass densities for eight low-K dielectric samples, based on an average value of γ obtained from the samples “ELK-2.2[3000A]” and “ELK-2.2[5000A]”. FIG. 10 is a plot of I/I₀ vs. nominal film thickness for the eight samples of FIG. 9 plus one other sample (“BD”=Black Diamond™). It is believed that departures of I/I₀ above the straight line indicate increasing porosity and so decreasing dielectric constant.

Other properties of interest, of low-K dielectric films on semiconductor wafers, that may be measured, directly or indirectly, by Raman spectroscopy include dielectric constant, index of refraction, purity, stress, and void content (i.e., porosity and pore size distribution), as well as (see Yoshio Nishi and Alain C. Diebold, eds. Handbook of Semiconductor Manufacturing Technology (Marcel Dekker, 2000) chapter 12, p. 357) thermal stability, glass transition temperature, Young's modulus, hardness, thermal expansion coefficient, adhesion strength, chemical resistance, chemical compatibility with a second material, permeability, gap fill capability, planarization ability and durability when subjected to CMP (chemical mechanical polishing).

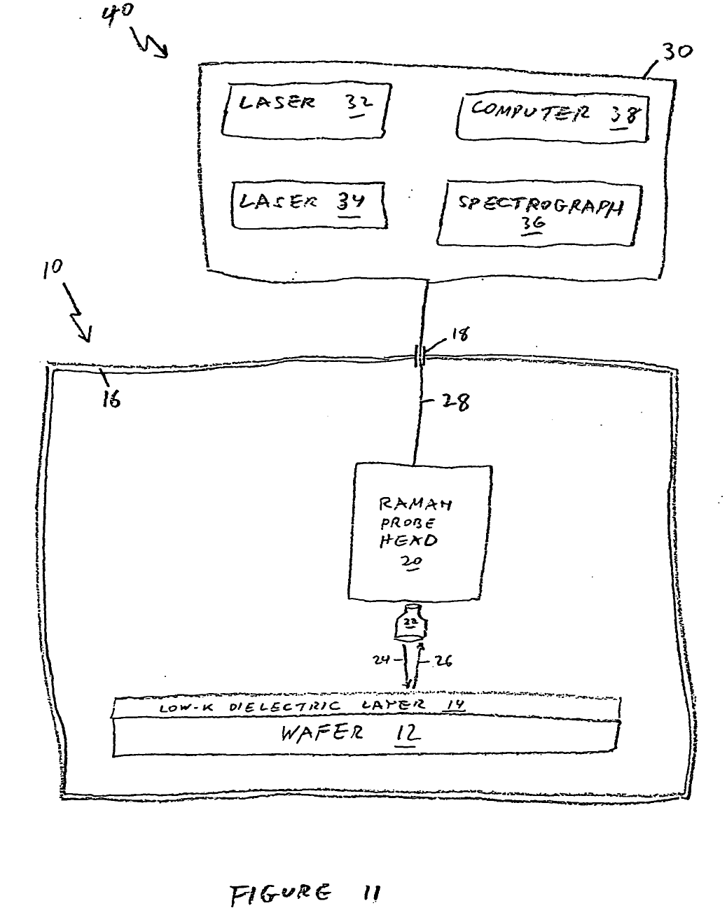

FIG. 11 is a schematic illustration, in cross-section, of a processing chamber 10 of the present invention. The spatial extent of processing chamber 10 is defined by a chamber housing 16. Within chamber housing 16 is a semiconductor wafer on which is being deposited, or on which has been deposited, a layer 14 of a low-K dielectric material. A measurement system 40 uses the method of the present invention to measure a relevant property of layer 14. For example, as layer 14 is deposited, measurement system 40 is used to measure the thickness of layer 14; and as layer 14 is annealed or cured, e.g. by being heated, subsequent to being deposited, measurement system 40 is used to measure the progress of the annealing or curing. The portion of measurement system 40 inside chamber housing 16 includes a Raman probe head 20, for example the Mark II Filtered Probehead of Kaiser Optical Systems or the RP-1 probehead of SpectraCode, collection optics 22 such as a microscope objective, and an optical fiber 28. Optical fiber 28 provides an optical connection, via a feedthrough 18 in chamber housing 16, to the rest of measurement system 40, which is housed external to processing chamber 10 in an external measurement system housing 30. The operational portion of measurement system 40 that is housed externally to processing chamber 10 includes two lasers 32 and 34 for generating incident light 24, a spectrograph 36 for resolving and recording the spectrum of Raman-scattered-light 26 that emerges from layer 14 in response to incident light 24, and a computer for performing signal processing on the spectrum recorded by spectrograph 36.

Two lasers 32 and 34 are used, to generate incident light 24 alternately at two different wavelengths, for reasons discussed below. Spectrograph 36 preferably is, for example, the spectrograph described by Battey et al. in U.S. Pat. No. 5,442,439, which patent is incorporated by reference for all purposes as if fully set forth herein. One advantage of the spectrograph of Battey et al. is that this spectrograph can handle Raman-scattered light in response to more than one excitation wavelength without the addition of moving parts and without the addition of complicated and expensive mechanisms. Collection optics 22 focus incident light 24 onto the portion of interest of layer 14. The lateral extent of this portion of layer 14 may be on the order of millimeters, on the order of microns, or even less than a micron, depending on the quality and complexity of collection optics 22 and on the desired application. Collection optics 22 also receives Raman-scattered light 26 from this portion of layer 14. This Raman scattered light 26 propagates via Raman probehead 20 and optical fiber 28 to spectrograph 36 for dispersion and analysis.

In an alternative configuration (not shown), Raman probehead 20 also is external to chamber housing 16. Incident light 24 is conveyed from Raman probehead 20 to collection optics 22, and Raman scattered light 26 is conveyed from collection optics 22 to Raman probehead 20, by an optical fiber similar to optical fiber 28.

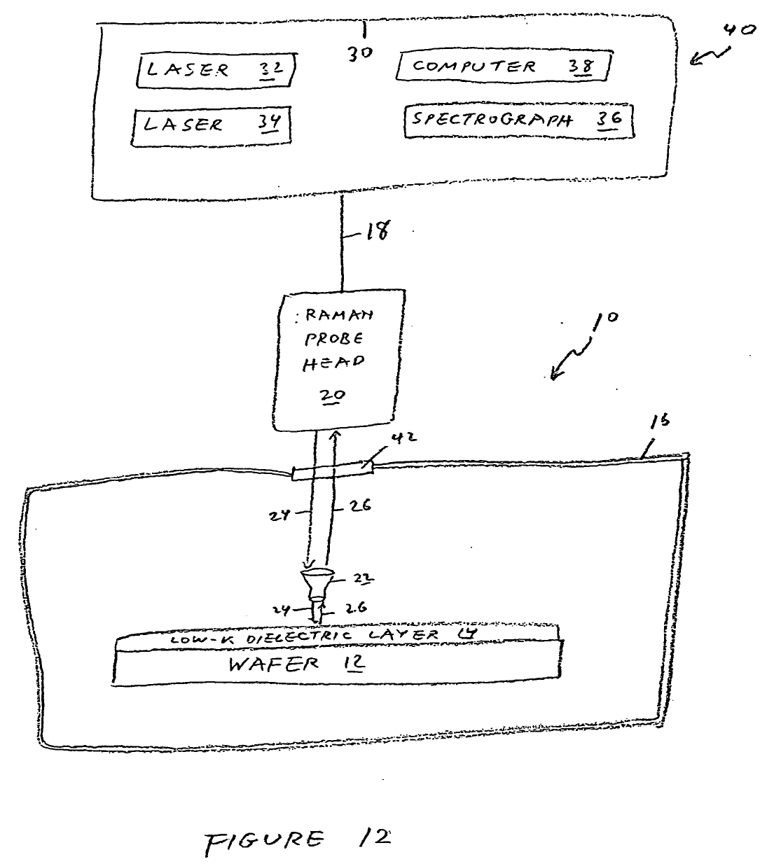

In a second alternative configuration, illustrated schematically in cross section in FIG. 12, Raman probehead 20 is external to chamber housing 20, and exchanges incident light 24 and Raman scattered light 26 with collection optics 28 via an optical window 42 in chamber housing 18.

It will be appreciated that no actual treatment of wafer 12a apart from the measurements performed by measurement system 40, need take place in chamber 10. In particular, the measurements performed in chamber 10 may be subsequent to and in advance of processing steps carried out in other, similar chambers.

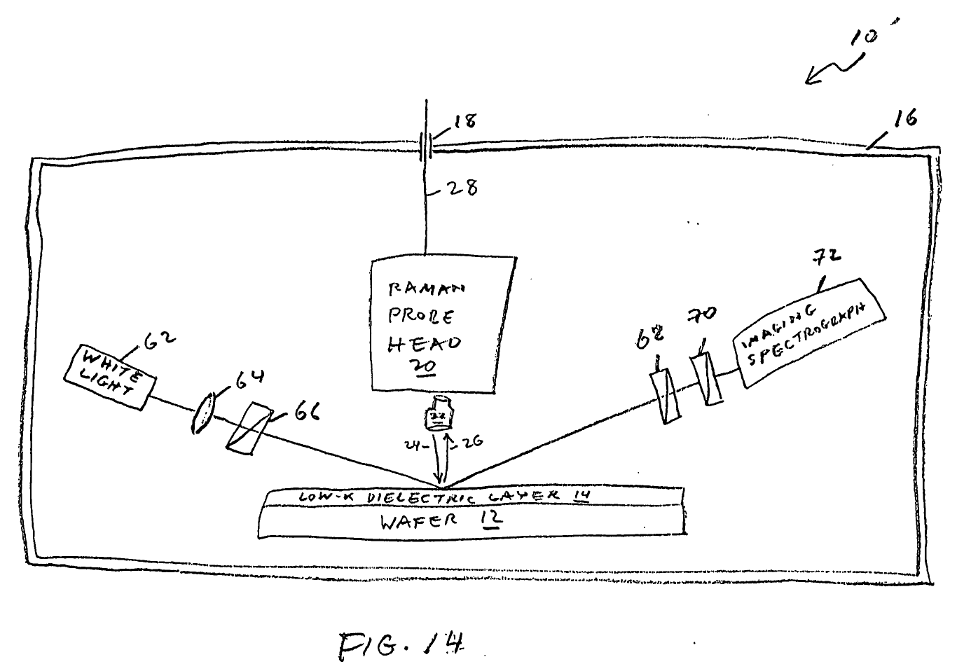

FIG. 14 is a partial schematic illustration, in cross-section, of a variant 10′ of processing chamber 10. Processing chamber 10′ includes, in addition to measurement system 40, the spectroscopic ellipsometer described by Fluckiger et al. in U.S. Pat. No. 6,052,188, which patent is incorporated by reference for all purposes as if fully set forth herein. This spectroscopic ellipsometer includes a source 62 of white incident light, a collimating lens 64 that collimates the white light, a polarizer 66 that polarizes the white light linearly, a retardation prism 68 that imposes spatially varying polarization shift on reflected polarized light, an analyzer 70 that converts the shifts to amplitude fringes, and an imaging spectrograph 72 that disperses the fringes. This combination of a Raman spectrometry system and a spectroscopic ellipsometer is used to measure the void content of layer 14, much as M. 1. Sanchez et al., in “Nanofoam porosity by infrared spectroscopy”, Journal of Polymer Science Part B: Polymer Physics, vol. 33 pp. 253-257 (1995) measured the porosity of polymer nanofoams using a combination of ellipsometry and FTIR spectroscopy.

It is well-known in the art of Raman spectroscopy that in many materials the intensity of the fluorescence spectrum is higher than the Raman spectrum, so much so that the Raman spectrum is overwhelmed by the fluorescence spectrum, and cannot be measured. However, since fluorescence usually decreases appreciably when the exciting laser wavelength increases towards the red and near infrared, often the Raman spectrum can be recovered by using a red or infrared exciting laser. In contrast, a second phenomenon is the one described in “Raman scattering by pure water and seawater”, by Jasmine S. Bartlett et al. Applied Optics vol.37 no.15 pp. 3324-3332 (20 May 1998), to wit, that the intensity of Raman scattering of water decreases with increasing laser excitation wavelength. More generally, it is well-known in the literature of Raman scattering that the Raman cross section, and hence the intensity of Raman scattered light, varies as the fourth power of the incident frequency, i.e. as the inverse fourth power of the incident wavelength. As a result, these are two examples that show that, whereas for many materials the Raman spectrum can only be observed with excitation wavelengths above 700-750 nm to overcome fluorescence, in some cases the best signals are obtained between 300 and 400 nm, with a decrease of about a factor of 3 to 4 between these two wavelengths.

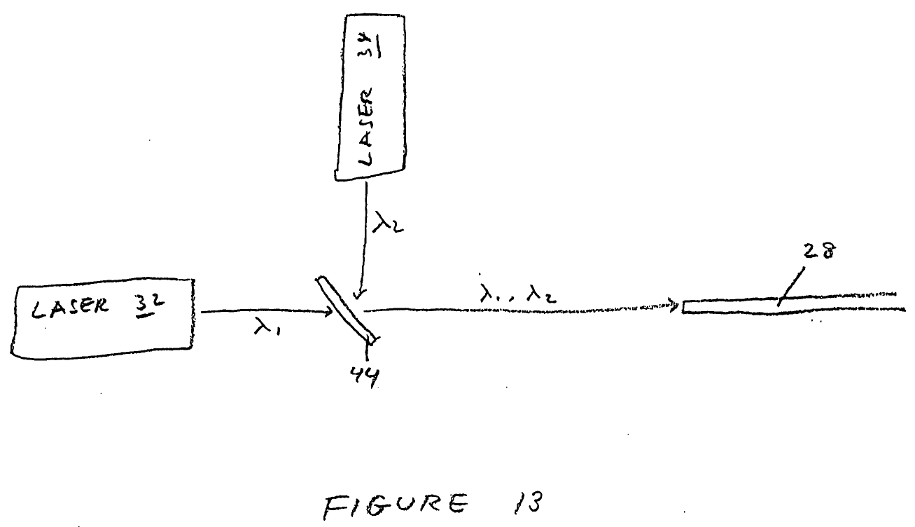

As a result, the fact that different materials give optimum Raman spectra for different excitation wavelengths, combined with the fact that most probably the semiconductor industry will adopt several low-K materials as dielectrics for manufacturing, it is advantageous to provide a compact Raman spectrograph for in-situ/in-line monitoring, which can work (simultaneously or sequentially) with at least two excitation wavelengths, one in the region of 300-500 nm, and one in the region of 600-800 nm. FIG. 13 shows, schematically, how this is accomplished within measurement system 40, using a dichroic filter 44 that transmits light of wavelength λ₁ and reflects light of wavelength λ₂. Laser 32 directs light of wavelength λ₁ towards dichroic filter 44. Laser 34 directs light of wavelength λ₂ towards dichroic filter 44. Dichroic filter 44 transmits the light of wavelength λ₁ towards optical fiber 28 and also reflects the light of wavelength λ₂ towards optical fiber 28. Both wavelengths of incident light 24 thus follow a common optical path from dichroic filter 44 to layer 14. Lasers 32 and 34 are switched on and off by computer 38 so that incident light 24 of wavelengths λ₁ and λ₂ can be used at will in order to optimize the Raman spectrum of layer 14. Note that the switching is accomplished without moving parts, and with minimal differential cost with respect to single wavelength excitation.

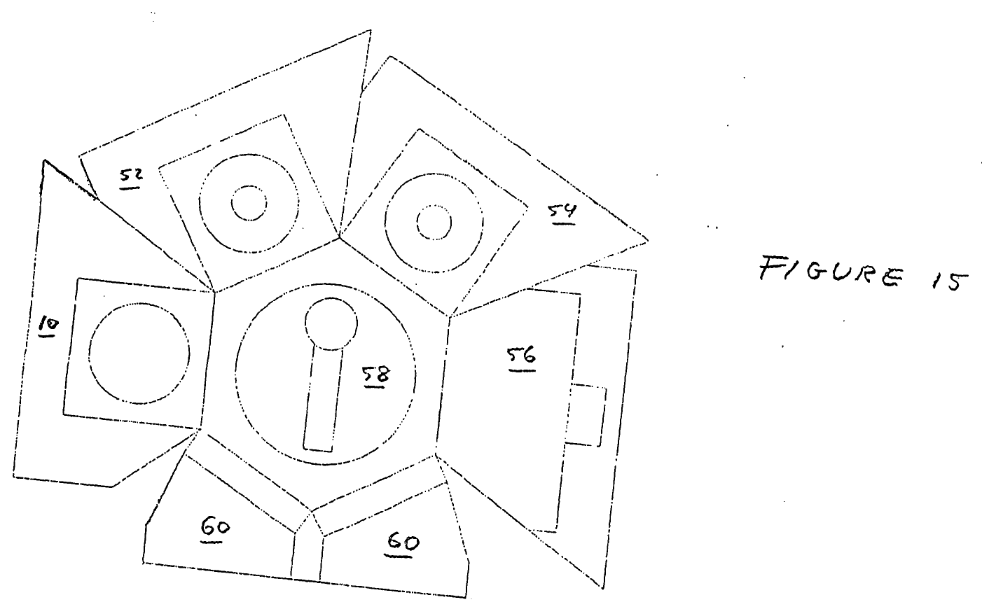

FIG. 15, which is adapted from Levy, U.S. Pat. No. 5,879,739, is a schematic illustration, in plan view, of a cluster tool 50, of the present invention, in which successive steps of the processing of wafer 12 are carried out. Cluster tool 50 includes a central hexagonal dealer 58 to which are attached chamber 10 and also three other chambers 52, 54 and 56 and two vacuum cassette handlers 60. Chambers 10, 52, 54 and 56 typically are vacuum chambers; alternatively, as in U.S. Pat. No. 5,879,739, one or more of chambers 10, 52, 54 and 56 are high-pressure chambers. Vacuum cassettes holding wafers 12 to be processed are introduced to cluster tool 50 and removed from cluster tool 50 via vacuum cassette handlers 60, and moved counterclockwise from chamber to chamber for processing by dealer 58. The relevant properties of layers 14 are measured in chamber 10 before subsequent processing without wafers 12 leaving cluster tool 50, thereby minimizing contamination of wafers 12.

In some cases, for the purpose of providing the industrially useful monitoring of some film properties, most of the relevant information is contained only in certain specific wavenumbers or in narrow wavenumber regions. In such cases, it is not necessary to acquire the entire Raman spectrum. Instead, data are collected only in the relevant wavenumbers and/or narrow wavenumber regions of the Raman spectrum. For this purpose, the monochromating elements of spectrograph 36 are replaced with the appropriate bandpass filters, and corresponding analytical algorithms are used by computer 38.

### 6. Fluorescence spectroscopy of SiCOH films

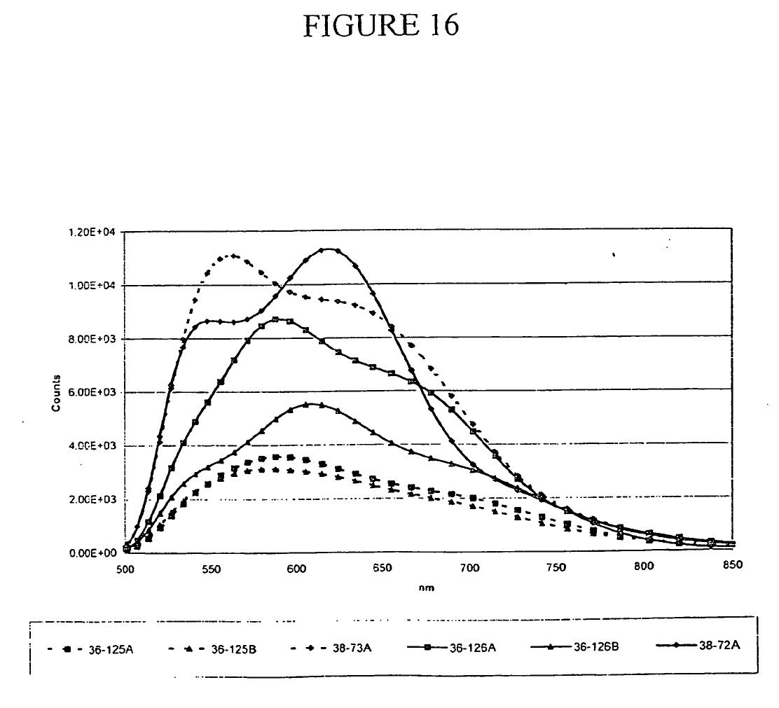

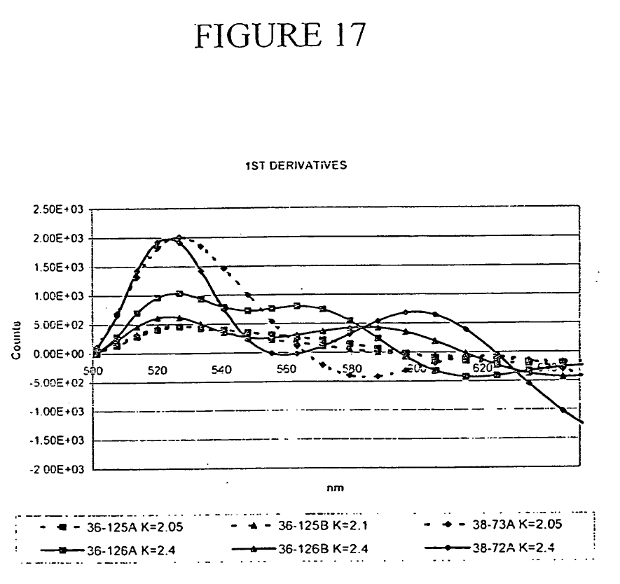

Measurement system 40, either using lasers 32 and 34 as sources of excitation light or using a xenon lamp instead of lasers 32 and 34 as a source of excitation light, is suitable for monitoring fluorescence that emerges from layer 14 in response to incident light from the xenon lamp. In particular, with the appropriate combination of “excitation-dichroic filters” used to attenuate scattered incident light by several orders of magnitude before the scattered incident light reaches the detector, the system is equally applicable to fluorescence measurements. Because fluorescence topically is much more intense than Raman scattering, the dynamic range of a typical measurement system 40 is too small for the two measurements to be done simultaneously, so that the two measurements usually must be done sequentially rather than simultaneously. The spectral plots of FIGS. 16 and 17 show that fluorescence spectroscopy is suitable for monitoring the dielectric constant of low-K materials.

The six samples (layers of SiCOH material on silicon) listed in the following table were prepared as described by A. Grill et al.:

| Sample code name | Annealing conditions | Dielectric constant |
|---|---|---|
| 36-125A | 400° C. in helium for 4 hours | 2.05 |
| 36-125B | 450° C. in helium for 2 hours | 2.1 |
| 36-126A | 400° C. in helium for 4 hours | 2.4 |
| 36-126B | 450° C. in helium for 2 hours | 2.4 |
| 38.72A | 400° C. in helium for 4 hours | 2.4 |
| 38.73A | 400° C. in helium for 4 hours | 2.05 |

Fluorescence spectra of these samples were measured using an Olympus fluorescence microscope model BX60 equipped with halogen illumination, a 10× magnification objective and a Chroma Wide Blue filter cube Faith dichroic filters, for excitation up to 490 nm and emission above 510 nm, and using a SpectraCube™ model SD300 of Applied Spectral Imaging Ltd. of Migdal HaEmek, Israel. The SpectraCube™ SD300 is an interferometer-based spectral imager. The measurement time was 5 seconds per spectral image at about 20 nm spectral resolution. Each spectral image included 200×200, pixels, so that each measurement acquired 40,000 spectra. Because each pixel was about 1 micron on a side, the size of the field of view to of each spectral image was about 200 microns by 20 microns. The spectral differences among the overwhelming majority of the pixels turned out to be insignificant, indicating that the samples were very uniform on a 200 micron scale.

FIG. 16 shows the spectra of one pixel for each measured sample. FIG. 17 shows the first derivatives of the curves of FIG. 16. The dashed lines refer to the samples with relatively low K K=2.05 or 2.1). The solid lines refer to the samples with relatively high K (K=2.4). The high-K curves all have two positive local maxima before turning permanently negative. The low-K cur %-es all have one positive local maximum before turning permanently negative.

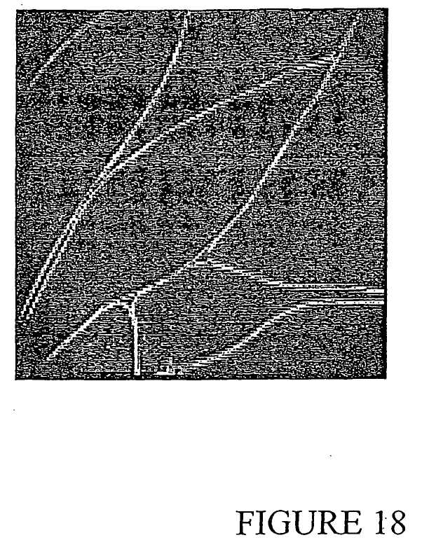

FIG. 18 illustrates the advantage of spectral imaging, i.e., simultaneous acquisition of the emission spectra from a plurality of locations on the sample, versus sequential acquisition of the emission spectra. As noted above, in each sample, the spectra of almost but not quite all of the pixels were substantially identical. FIG. 18 is an image of a region of sample 38-73A, as acquired using the SpectraCube™ and the fluorescence microscope as described above. The bright lines are cracks on the low-K dielectric layer. The relatively uniform dark regions between the bright lines are the uniform regions of low-K material whose spectrum is shown in FIG. 16. Histogram-based algorithms may be used to distinguish the overwhelming majority of pixels, whose spectra actually characterize such a low-K dielectric layer, from pixels with spurious spectra.

The origin and behavior of fluorescence in porous silicates and silica glasses is not yet understood scientifically (Prof. Renata Reisfeld, Chemistry Dept. of the Hebrew University, Israel, private communication). If the above results will be proven to be repeatable and effectively correlated with the dielectric constant K of low-K porous materials, then this method can be used as an indirect method of monitoring important properties of low-K materials in production.

While the invention has been described with respect to a limited number of embodiments, it will be appreciated that many variations, modifications and other applications of the invention may be made.

1. A method of processing a workpiece, comprising the steps of:
(a) applying a layer of a first material to the workpiece; and
(b) measuring a property of said layer by steps including:
(i) exciting at least a first portion of said layer with incident light, and
(ii) monitoring light that is emitted from said at least first portion in response to said incident light.

2. The method of claim 1, wherein said first material is a low-K dielectric.

3. The method of claim 1, wherein said property is selected from the group consisting of dielectric constant, index of refraction moisture content, purity, thermal stability, cure progress, glass transition temperature, stress, Young's modulus, hardness, thermal expansion coefficient, adhesion strength, chemical resistance, chemical compatibility with a second material, permeability, gap fill capability, planarization ability, layer thickness, void content and durability under chemical mechanical polishing.

4. The method of claim 1, wherein said measuring is effected during said applying.

5. The method of claim 1, further comprising the step of:
(c) treating said layer, subsequent to said applying;
and wherein said measuring is effected during said treating.

6. The method of claim 5, wherein said treating includes heating the workpiece.

7. The method of claim 5, wherein said treating includes stripping a photoresist from said workpiece.

8. The method of claim 1, wherein said monitoring includes measuring a spectrum of said light that is emitted in response to said incident light.

9. The method of claim 8, wherein said measuring is effected substantially simultaneously with respect to a plurality of locations on the workpiece wherefrom said light, that is emitted in response to said incident light, is emitted.

10. The method of claim 1, wherein said monitoring includes measuring said light that is emitted in response to said incident light at only a single wavenumber.

11. The method of claim 10, wherein said measuring is effected substantially simultaneously with respect to a plurality of locations on the workpiece wherefrom said light, that is emitted in response to said incident light, is emitted.

12. The method of claim 1, wherein said monitoring includes measuring said light that is emitted in response to said incident light at only a plurality of discrete wavenumbers.

13. The method of claim 12, wherein said measuring is effected substantially simultaneously with respect to a plurality of locations on the workpiece wherefrom said light, that is emitted in response to said incident light, is emitted.

14. The method of claim 1, wherein said incident light is substantially monochromatic.

15. The method of claim 1, wherein said exciting is effected using a plurality of different discrete incident wavelengths.

16. The method of claim 1, wherein said light that is emitted in response to said incident light includes Raman scattered light.

17. The method of claim 16, wherein said measuring further includes the step of:
(iii) subjecting at least a second portion of said layer to a measurement technique selected from the group consisting of ellipsometry, spectroscopy, reflectometry and transmissometry.

18. The method of claim 17, wherein said spectroscopy is fluorescence spectroscopy.

19. The method of claim 17, wherein said spectroscopy is in a spectral region selected from the group consisting of visible, near infrared and mid-infrared.

20. The method of claim 17, wherein said at least first portion and said at least second portion are substantially identical.

21. The method of claim 1, wherein said light that is emitted in response to said incident light includes fluorescence.

22. The method of claim 1, wherein said exciting and said monitoring are effected using a probehead.

23. The method of claim 22, wherein the processing is effected inside a processing chamber, and wherein said probehead is inside said chamber.

24. The method of claim 22, wherein the processing is effected inside a processing chamber, and wherein said probehead is outside said chamber.

25. A chamber for processing a workpiece, comprising:
(a) a chamber housing wherein the workpiece is placed for processing; and
(b) a probehead for exciting at least a portion of the workpiece with incident light and for receiving light that is emitted from said at least portion in response to said incident light.

26. The chamber of claim 25, wherein said light that is emitted from said at least portion in response to said incident light includes Raman scattered light.

27. The chamber of claim 25, wherein said light that is emitted from said at least portion in response to said incident light includes fluorescence.

28. The chamber of claim 25, further comprising:
(c) at least one laser for providing said incident light.

29. The chamber of claim 25, further comprising:
(c) a xenon lamp for providing said incident light.

30. The chamber of claim 25, further comprising:
(c) a spectrograph for analyzing said light that is emitted in response to said incident light.

31. The chamber of claim 25, wherein said probehead is inside said chamber housing.

32. The chamber of claim 25, wherein said probehead is outside said chamber housing, the chamber further comprising:
(c) a window in said chamber housing, wherethrough said probehead delivers said incident light to said at least portion of the workpiece and wherethrough said probehead receives said light that is emitted in response to said incident light.

33. The chamber of claim 25, further comprising:
(c) an ellipsometer for effecting ellipsometry of said at least portion of the workpiece.

34. A cluster tool comprising the chamber of claim 25.

35. An analytic instrument comprising:
(a) a Raman probehead for exciting an object with incident light and for receiving Raman-scattered light from said object;
(b) a first source for providing said incident light at a first wavelength; and
(c) a second source for providing said incident light at a second wavelength.

36. The analytic instrument of claim 35, wherein said sources include respective lasers.

37. The analytic instrument of claim 35, wherein said sources provide said incident light to said Raman probehead at least in part along a common optical path, the analytic instrument further comprising:
(d) a mechanism for directing said incident light from both said sources to said common optical path.

38. The analytic instrument of claim 37, wherein said mechanism is stationary.

39. The analytic instrument of claim 37, wherein said mechanism includes a dichroic filter that reflects said incident light of said first wavelength and transmits said incident light of said second wavelength.

40. A method of processing a workpiece bearing a layer of a first material, comprising the steps of:
(a) exciting at least a first portion of the layer with incident light, and
(b) monitoring light that is emitted from said at least first portion in response to said incident light, in order to measure a property of the layer.

41. The method of claim 40, wherein said property is selected from the group consisting of dielectric constant, index of refraction, moisture content, purity, thermal stability, cure progress, glass transition temperature, stress, Young's modulus, hardness, thermal expansion coefficient, adhesion strength, chemical resistance, chemical compatibility with a second material, permeability, gap fill capability, planarization ability, layer thickness Avoid content and durability under chemical mechanical polishing.

42. The method of claim 40, wherein said exciting and said monitoring are effected while the layer is being applied to the workpiece.

43. The method of claim 40, wherein said exciting and said monitoring are effected after the layer has been applied to the workpiece.

44. The method of claim 40, wherein said monitoring includes measuring a spectrum of said light that is emitted in response to said incident light.

45. The method of claim 44, wherein said measuring is effected substantially simultaneously with respect to a plurality of locations on the workpiece wherefrom said light, that is emitted in response to said incident light, is emitted.

46. The method of claim 40, wherein said monitoring includes measuring said light that is emitted in response to said incident light at only a single wavenumber.

47. The method of claim 46, wherein said measuring is effected substantially simultaneously with respect to a plurality of locations on the workpiece wherefrom said light, that is emitted in response to said incident light, is emitted.

48. The method of claim 40, wherein said monitoring includes measuring said light that is emitted in response to said incident light at only a plurality of discrete wavenumbers.

49. The method of claim 48, wherein said measuring is effected substantially simultaneously with respect to a plurality of locations on the workpiece wherefrom said light, that is emitted in response to said incident light, is emitted.

50. The method of claim 40, wherein said incident light is substantially monochromatic.

51. The method of claim 40, wherein said exciting is effected using a plurality of different discrete incident wavelengths.

52. The method of claim 40, wherein said light that is emitted in response to said incident light includes Raman scattered light.

53. The method of claim 52, further comprising the step of:
(c) subjecting at least a second portion of the layer to a measurement technique selected from the group consisting of ellipsometry, spectroscopy, reflectometry and transmissometry.

54. A The method of claim 53, wherein said spectroscopy is fluorescence spectroscopy.

55. The method of claim 53, wherein said spectroscopy is in a spectral region selected from the group consisting of visible, near infrared and mid-infrared.

56. The method of claim 53, wherein said at least first portion and said at least second portion are substantially identical.

57. The method of claim 40, wherein said light that is emitted in response to said incident light includes fluorescence.

58. The method of claim 40, wherein said exciting and said monitoring are effected using a probehead.

59. The method of claim 58, wherein said exciting and said monitoring are effected inside a processing chamber, and wherein said probehead is inside said chamber.

60. The method of claim 58, wherein said exciting and said monitoring are effected inside a processing chamber, and wherein said probehead is outside said chamber.
